(19) United States
(12) Patent Application Publication
(10) Pub. No.: US 2026/0122982 A1
(43) Pub. Date: Apr. 30, 2026

(54) RADIATION-HARDENED SILICON CARBIDE METAL-OXIDE-SEMICONDUCTOR FIELD-EFFECT TRANSISTOR DEVICE STRUCTURE AND PREPARATION METHOD THEREOF

(71) Applicant: Hunan University, Changsha (CN)

(72) Inventors: Shiwei Liang, Changsha (CN); Lu Mi, Changsha (CN); Jiaqi Chen, Changsha (CN)

(21) Appl. No.: 19/283,322

(22) Filed: Jul. 29, 2025

(30) Foreign Application Priority Data
Oct. 30, 2024 (CN) 202411535150.2

(51) Int. Cl. H10D 62/10; H10D 30/66; H10D 62/00; H10D 62/832

(52) U.S. Cl. CPC H10D 62/109; H10D 30/668; H10D 62/054; H10D 62/8325

(57) ABSTRACT

A radiation-hardened silicon carbide metal-oxide-semiconductor field-effect transistor (SiC MOSFET) device structure and a preparation method thereof, comprising an N⁻ drift layer, an N⁺ substrate layer is arranged beneath the N⁻ drift layer, a carrier storage layer is arranged above the N⁻ drift layer, a source metal layer is arranged above the carrier storage layer, a junction field-effect transistor (JFET) region is arranged in a middle beneath the source metal layer, a trench is introduced inside the JFET region, an interior of the trench is provided with a P-type doped region and a filling region, P-base regions are arranged on both sides of the trench, N⁺ source regions and P⁺ regions are arranged in the P-base regions. The invention significantly reduces electric field strength in the thin gate oxide, thereby enhancing the single-event gate rupture immunity of the device.

### 1. TECHNICAL FIELD

The invention relates to the technical field of radiation hardening, in particular to a radiation-hardened silicon carbide metal-oxide-semiconductor field-effect transistor (SiC MOSFET) device structure and a preparation method thereof.

### 2. BACKGROUND ART

Silicon Carbide (SiC) high-voltage power devices exhibit superior electrothermal performance compared with traditional silicon devices and can operate normally under more severe environmental conditions. Therefore, they hold broad application prospects in fields such as photovoltaic power generation, electric vehicles, and aerospace. For the aerospace field, in addition to meeting the requirements of high voltage, high power, high frequency, and low loss, power devices must also possess excellent radiation hardening capabilities.

For high-voltage SiC power devices, radiation hardening is a major challenge. Current SiC power devices often experience single-event burnout at less than one-third of the blocking voltage and with a linear energy transfer (LET) of no higher than 10 MeV·cm²/mg, far below theoretical expectations. Single event effect typically involves a very complex electro-thermal coupling response within the device. When heavy ions strike into the power device, they generate a large number of electron-hole pairs along the trajectory of motion. Under the influence of the electric field, these electron-hole pairs drift, creating an extremely high instantaneous current inside the device. Some electrons and holes also accumulate at both ends of the device, thereby restructuring the electric field inside the device, leading to localized strong impact ionization in the device by extremely high electric field, such as single-event gate rupture. In addition, the massive electron-hole movement and the strong coupling of the electric field within the device generate significant instantaneous heat, which could cause localized single-event burnout in the device. For conventional planar SiC MOSFETs, the junction field-effect transistor (JFET) region is the most sensitive to single event effect due to the strongest electric field strength present during the forward blocking state.

To address the shortcomings of the prior art, a trench is introduced into the JFET region, and P-type impurities are implanted into sidewalls and a bottom of the trench to form a P-type doped region, the trench is filled with high-concentration P-type and N-type polysilicon, the N-type polysilicon is surrounded by P-type polysilicon. The trench structure transfers the strong electric field at an interface between gate oxide and the JFET region to a bottom of the JFET region, significantly reducing the electric field strength in the thin gate oxide, thereby enhancing the single-event gate rupture (SEGR) immunity of the SiC MOSFET device. Meanwhile, the P-type doped region at the bottom and sidewalls of the trench, along with the P-type polysilicon shorted to the source in the trench, increases the area of hole extraction path within the active region, thereby improving the efficiency of internal hole extraction at the moment of heavy ion strike. Additionally, the pinch-off effect of the JFET at high blocking voltage is strengthened due to the introduction of the trench structure; this allows for an increased doping concentration in the carrier storage layer without compromising voltage blocking capability of the device; the higher doping concentration in the carrier storage layer and the N-type polysilicon in the trench shorted to the source significantly enhance the recombination efficiency of holes and electrons at the moment of single event effect, further improving the extraction speed of excess carriers.

### 3. SUMMARY OF THE INVENTION

The invention aims to provide a radiation-hardened SiC MOSFET device structure and a preparation method thereof. This significantly reduces the electric field strength in the thin gate oxide, thereby improving the single-event gate rupture immunity of the SiC MOSFET device. The process complexity is low, requiring only the addition of trench etching, P-type ion implantation on sidewalls and a bottom of the trench, and trench refill processes, etc.

The invention provides a radiation-hardened SiC MOSFET device structure and a preparation method thereof, comprising an N⁻ drift layer, an N⁺ substrate layer is arranged beneath the N⁻ drift layer, a drain metal layer is arranged beneath the N⁺ substrate layer, a carrier storage layer is arranged above the N⁻ drift layer, a source metal layer is arranged above the carrier storage layer, a junction field-effect transistor (JFET) region is arranged in a middle beneath the source metal layer, and a trench is introduced inside the JFET region, an interior of the trench is provided with a P-type doped region and a filling region, P-base regions are arranged on both sides of the trench, N⁺ source regions and P⁺ regions are arranged in the P-base regions,

Preferably, the source metal layer is provided with interlayer dielectric layers and polysilicon layers, the polysilicon layers are located inside the interlayer dielectric layers.

Preferably, the number of the P-base regions is two, each P-base region is located on either side of the trench, each P-base region is provided with two N⁺ source regions and one P⁺ region, the N⁺ source regions and the P⁺ region within each P-base region are arranged side by side, the N⁺ source regions are positioned in a middle of the P⁺ region.

Preferably, the P-type doped region is provided with P-type impurities, the P-type doped region is located on the sidewalls and the bottom of the trench, this filling region is filled with a P-type polysilicon and an N-type polysilicon, the N-type polysilicon is surrounded by the P-type polysilicon, and the filling region is located within the P-type doped region.

Preferably, the number of the interlayer dielectric layers and the polysilicon layers is several.

Preferably, the preparation method comprises the following steps:
S1: the trench is introduced in the JFET region, and P-type impurities are implanted into the sidewalls and the bottom of the trench to form the P-type doped region;
S2: the filling region inside the trench is filled with high-concentration P-type polysilicon and N-type polysilicon, with the N-type polysilicon surrounded by the P-type polysilicon;
S3: the trench transfers the strong electric field at an interface between gate oxide and the JFET region to a bottom of the JFET region;
S4: the P-type doped region is shorted to the source of the P-type polysilicon.

Therefore, the invention adopts the radiation-hardened SiC MOSFET device structure and the preparation method thereof. A trench structure is introduced into the JFET region of the SiC MOSFET device, P-type impurities are implanted into the sidewalls and the bottom of the trench to form the P-type doped region, and the trench is filled with high-concentration P-type polysilicon. The trench structure transfers the strong electric field at the interface between the gate oxide and the JFET region to the bottom of the JFET region, significantly reducing the electric field strength in the thin gate oxide, thereby enhancing the single-event gate rupture immunity of the SiC MOSFET device.

The P-type doped region on the bottom and the sidewalls of the trench, as well as the P-type polysilicon shorted the source in the trench, enhance the hole extraction efficiency near the JFET region at the moment of heavy ion strike. This allows for rapid and efficient removal of electron-hole pairs generated by heavy ion strike, reducing the current induced by single-event effect and the radiation response time, effectively improving the capability of the SiC MOSFET to withstand single-event effect.

Additionally, due to the introduction of the trench structure, the pinch-off effect of the JFET at high blocking voltage is strengthened. This allows for an increased doping concentration in the carrier storage layer without compromising voltage blocking capability of the device, thereby improving the recombination efficiency of holes and electrons at the moment of single event effect and enhancing the radiation resistance of the SiC MOSFET device.

The process complexity is low, requiring only the addition of trench etching, P-type ion implantation on the sidewalls and the bottom of the trench, and trench refill processes, etc.

The technical solution of the invention is further described in detail below through the accompanying drawings and embodiments.

### 4. BRIEF DESCRIPTION OF ACCOMPANYING DRAWINGS

FIG. 1 is an overall schematic diagram of a radiation-hardened SiC MOSFET device structure and a preparation method of the invention.

FIG. 2 is an overall flow chart of the radiation-hardened SiC MOSFET device structure and the preparation method of the invention.

In the figures:
1 N⁻ drift layer; 2 N⁺ substrate layer; 3 drain metal layer; 4 carrier storage layer; 5 source metal layer; 6 JFET region; 7 trench; 8 P-type doped region; 9 filling region; 10 P-base region; 11 N⁺ source region; 12 P⁺ region; 13 interlayer dielectric layer; 14 polysilicon layer.

### 5. SPECIFIC EMBODIMENT OF THE INVENTION

The technical solution of the invention is further described below through the accompanying drawings and embodiments.

Unless otherwise defined, the technical or scientific terms used in the invention should have their generally accepted meanings as understood by those of ordinary skill in the field to which the invention pertains.

The terms “first”, “second”, and similar terms used in the invention do not imply any sequence, quantity, or importance, but are merely used to distinguish different components. The terms “include” or “comprise” and similar words indicate that the elements or objects listed after these terms are covered by the preceding ones, including their equivalents, without excluding other elements or objects. The terms “connected” or “linked” and similar words are not limited to physical or mechanical connections, but may also include electrical connections, whether direct or indirect. The terms “up”, “down”, “left”, “right”, etc., are used solely to indicate relative positional relationships, and such relationships may change accordingly when the absolute position of the described object changes.

### Embodiment 1

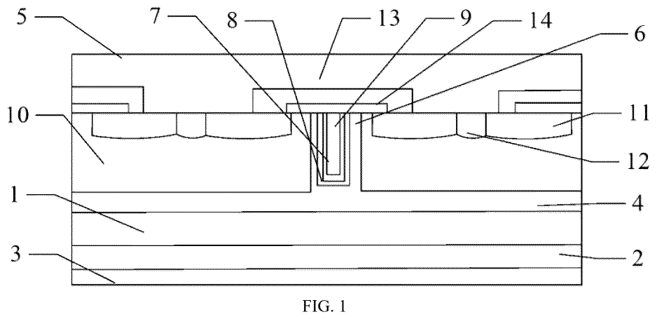

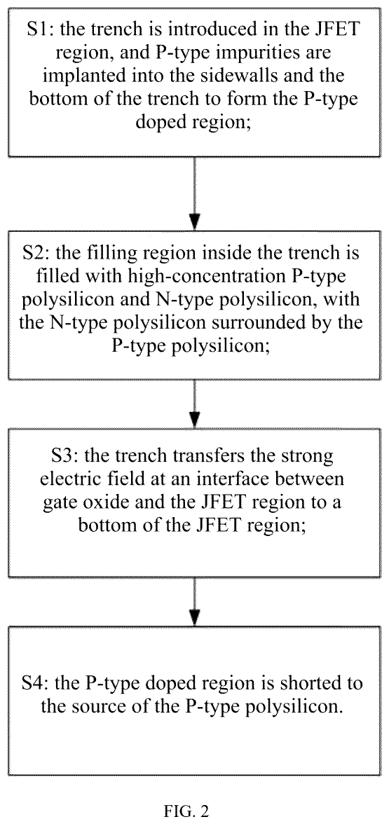

Please refer to FIGS. 1 to 2, the invention provides a radiation-hardened SiC MOSFET device structure and a preparation thereof, comprising a source metal layer 5, interlayer dielectric layers 13, a carrier storage layer 4, an N⁻ drift layer 1, an N⁺ substrate layer 2, a drain metal layer 3, P-base regions 10, N⁺ source regions 11, P⁺ regions 12 and a JFET region 6; the device comprises the N drift layer 1, which withstands high voltage and reduces on-resistance; the N⁺ substrate layer 2 is arranged beneath the N⁻ drift layer 1, and the N⁺ substrate layer 2 reduces the contact resistance of the device and improves current transmission efficiency.

The drain metal layer 3 is arranged beneath the N⁺ substrate layer 2, the drain metal layer 3 provides electrical connection to an external circuit, ensuring normal operation. The carrier storage layer 4 is arranged above the N⁻ drift layer, which is used to store charges or carriers (electrons or holes), and can dynamically store and release charges during the operation of the device.

The source metal layer 5 is provided with interlayer dielectric layers 13 and polysilicon layers 14, the polysilicon layers 14 are located inside the interlayer dielectric layers 13. The in interlayer dielectric layers are insulating materials, typically located between the source metal layer 5 and the active region of the device (such as the JFET region 6); they provide electrical isolation to prevent a short circuit between the source metal layer 5 and the active region.

Meanwhile, the interlayer dielectric layers 13 can also serve as a supporting structure to maintain the relative positional stability between the source metal layer 5 and the active region.

Within the source metal layer 5, the polysilicon layers 14 may be utilized to form specific electric fields or carrier transport paths.

By adjusting the shape, size, and doping concentration of the polysilicon layers 14, the current-voltage characteristics, switching speed, and stability of the device can be optimized.

The polysilicon layers 14 are located within the interlayer dielectric layers 13, which means they are surrounded by the insulating materials. This arrangement prevents direct contact between the polysilicon layers 14 and the source metal layer 5 or the active region, thereby avoiding unnecessary current leakage or short circuits. Meanwhile, the interlayer dielectric layers 13 also serve as a supporting and protective layer for the polysilicon layers 14, preventing them from being damaged during the manufacturing process or use.

By introducing the polysilicon layers 14 and the interlayer dielectric layers 13 within the source metal layer 5, the electric field distribution and carrier behavior within the device can be further optimized. This contributes to enhancing the breakdown voltage of the device, reducing the on-resistance, improving the switching speed, and strengthening the stability.

The number of the interlayer dielectric layers 13 and the polysilicon layers 14 is several. The use of multiple interlayer dielectric layers 13 can provide better electrical isolation and supporting effects. Different interlayer dielectric layers 13 can have varying thicknesses and materials to meet diverse requirements for electric fields and carrier transport. The multi-layer structure also helps reduce internal stresses within the device, thereby enhancing its mechanical stability. The role of multiple polysilicon layers: multiple layers of polysilicon 14 can form complex electric fields and carrier transport paths within the source metal layer 5. By adjusting the shape, size, and doping concentration of different polysilicon layers, the current-voltage characteristics, switching speed, and stability of the device can be precisely controlled.

The structure of multiple polysilicon layers 14 can also be employed to achieve specific functions, such as charge storage, electric field shielding, or current limitation. Arrangement and combination of interlayer dielectric layers 13 and polysilicon layers 14: the interlayer dielectric layers 13 and polysilicon layers 14 can be combined in a specific sequence and arrangement to form the desired electric fields and carrier transport paths. Precise alignment and connection between different interlayer dielectric layers 13 and polysilicon layers 14 can be achieved through process steps such as etching, deposition, or implantation.

Impact on device performance: by using multiple interlayer dielectric layers 13 and polysilicon layers 14, the electric field distribution and carrier behavior of the device can be further optimized. This helps improve the breakdown voltage, reduce the on-resistance, increase the switching speed, and enhance stability. The multilayer structure helps reduce noise and interference in the device, improves the signal-to-noise ratio, and enables more complex functions and characteristics.

The source metal layer 5 is arranged above the carrier storage layer 4, and serves as the source (or emitter) of the device, forming an electrical connection with the external circuit and providing a path for carrier injection or extraction. The source metal layer 5 forms a good ohmic contact with the carrier storage layer 4 through welding, sintering, or other metallization processes to ensure efficient current transmission. The JFET region 6 is arranged in a middle beneath the source metal layer 5, it regulates the current between the source and the drain by controlling the gate voltage, acting as a current-controlling element that dynamically adjusts the current magnitude during device operation; the source metal layer 5 forms a good electrical contact with the JFET region 6 through metallization processes. The source metal layer 5 provides the electrical connection between the external circuit and the JFET region 6, enabling the external circuit to control the gate voltage of the JFET region 6 and thereby regulating the device's current.

A trench 7 is introduced inside the JFET region 6, and the trench 7 is a recess or channel etched or formed within the JFET region 6. The introduction of trench 7 can alter the electric field distribution and carrier transport characteristics in the JFET region 6, allowing for fine-tuning of the device's performance. The trench 7 can change the resistance distribution in the JFET region 6, causing the current to form a concentrated flow path near the trench 7, which helps reduce the on-resistance of the device. As a region for carrier injection or extraction, the trench 7 enhances the carrier control ability of the device; the trench 7 can also serve as a transport channel for carriers from the storage layer to the JFET region 6, further enhancing the carrier control ability of the device. An interior of the trench is provided with a P-type doped region and a filling region. The presence of the P-type doped region 8 forms a localized P-type semiconductor area, which creates a PN junction with the surrounding N-type semiconductor region. The PN junction can alter the electric field distribution near the trench, affecting carrier transport and storage.

The P-type doped region 8 is provided with P-type impurities, and the P-type doped region 8 is located on sidewalls and a bottom of the trench 7, the P-type doped region 8 is an area in the semiconductor material where P-type impurities (such as boron) have been doped, rendering this region a P-type semiconductor. The P-type doped region 8 is located on the sidewalls and the bottom of the trench 7, with an entire surface of the trench 7 covered by the P-type semiconductor material. This arrangement facilitates the formation of the desired electric fields and carrier transport paths near the trench 7, thereby optimizing the performance of the device.

The filling region 9 is filled with a P-type polysilicon and an N-type polysilicon, and the N-type polysilicon is surrounded by the P-type polysilicon, which helps form a specific electric field distribution and carrier transport path within the filling region 9. The filling region 9 is located inside the P-type doped region 8. By setting the P-type doped region 8 on the sidewalls and the bottom of trench 7, and filling it with P-type polysilicon and N-type polysilicon, the electric field distribution and carrier behavior of the device can be optimized. This helps reduce the on-resistance of the device, improve the breakdown voltage, and enhance the stability of the device.

At the same time, the combination of P-type polysilicon and N-type polysilicon in the filling region 9 can also be used to achieve specific functions, such as charge storage, electric field shielding, or current limiting.

P-base regions 10 are arranged on both sides of the trench 7; the P-type region, along with the P-type doped region 8 inside the trench 7 and the surrounding N-type semiconductor region, together form a complex PN junction structure. The P-base regions 10 are provided with N⁺ source regions 11 and P⁺ regions 12. The N⁺ source regions are heavily doped N-type semiconductor regions formed within the P-base regions 10. The role of the N⁺ source regions 11 is to serve as current injection regions for the device, providing channels for carriers (electrons) to enter the JFET region 6. By adjusting the doping concentration and shape of the N⁺ source regions 11, the current-voltage characteristics of the device can be optimized, the on-resistance can be reduced, and the switching speed can be improved.

The P⁺ regions 12 are heavily doped P-type semiconductor regions formed within the P-base regions 10. The main function of the P⁺ regions 12 is to serve as control regions of the device, controlling the current flow in the JFET region 6 by changing the voltage of the P regions 12. When the voltage of the P⁺ regions 12 changes, the electric field distribution near the trench 7 and within the P-base regions 10 changes, thereby affecting the transport and storage of carriers, and controlling the switching state of the device.

The number of the P-base regions 10 is two, each P-base region 10 is located on either side of the trench 7, this helps form symmetric electric fields and carrier transport paths on both sides of the trench 7, thereby optimizing the performance of the device. Each P-base region 10 is provided with two N⁺ source regions 11, with two heavily doped N-type regions in each P-base region 10 serving as current injection regions. Each P-base region 10 is provided with one P⁺ region 12, which is used to control the electric field distribution and carrier behavior near the trench 7 and within the P-base regions 10. The N⁺ source regions 11 and the P⁺ region 12 within each P-base region 10 are arranged side by side, and the N⁺ source regions 11 are positioned in a middle of the P⁺ region 12; this arrangement helps optimize the electric field and carrier transport between the N⁺ source regions 11 and the trench 7 under the control of the P⁺ region 12.

S1: the trench is introduced in the JFET region, and P-type impurities are implanted into the sidewalls and the bottom of the trench to form the P-type doped region;

S2: the filling region inside the trench is filled with high-concentration P-type polysilicon and N-type polysilicon, with the N-type polysilicon surrounded by the P-type polysilicon;

S3: the trench transfers the strong electric field at an interface between gate oxide and the JFET region to a bottom of the JFET region;

S4: the P-type doped region at the bottom and the sidewalls of the trench is shorted with the source of the P-type polysilicon inside the trench.

Therefore, the invention adopts the radiation-hardened SiC MOSFET device structure and the preparation method thereof. A trench structure is introduced into the JFET region of the SiC MOSFET device, P-type impurities are implanted into the sidewalls and the bottom of the trench to form the P-type doped region, and the trench is filled with high-concentration P-type polysilicon. The trench structure transfers the strong electric field at the interface between the gate oxide and the JFET region to the bottom of the JFET region, significantly reducing the electric field strength in the thin gate oxide, thereby enhancing the single-event gate rupture immunity of the SiC MOSFET device.

The P-type doped region on the bottom and the sidewalls of the trench, as well as the P-type polysilicon shorted the source in the trench, enhance the hole extraction efficiency near the JFET region at the moment of heavy ion strike. This allows for rapid and efficient removal of electron-hole pairs generated by heavy ion strike, reducing the current induced by single-event effect and the radiation response time, effectively improving the capability of the SiC MOSFET to withstand single-event effect.

Additionally, due to the introduction of the trench structure, the pinch-off effect of the JFET at high blocking voltage is strengthened. This allows for an increased doping concentration in the carrier storage layer without compromising voltage blocking capability of the device, thereby improving the recombination efficiency of holes and electrons at the moment of single event effect and enhancing the radiation resistance of the SiC MOSFET device.

The process complexity is low, requiring only the addition of trench etching, P-type ion implantation on the sidewalls and the bottom of the trench, and trench refill processes, etc.

The above embodiments are only used to describe the technical solutions of the invention rather than to limit it. Although the invention has been described in detail with reference to the preferred embodiments, those skilled in the art should understand that they can still modify or replace the technical solution of the invention with equivalents, and these modifications or equivalent replacements cannot cause the modified technical solution to deviate from the spirit and scope of the technical solution of the invention.

1. A radiation-hardened silicon carbide metal-oxide-semiconductor field-effect transistor (SiC MOSFET) device structure, comprising an N⁻ drift layer, an N⁺ substrate layer is arranged beneath the N⁻ drift layer, a drain metal layer is arranged beneath the N⁺ substrate layer, a carrier storage layer is arranged above the N⁻ drift layer, a source metal layer is arranged above the carrier storage layer, a junction field-effect transistor (JFET) region is arranged in a middle beneath the source metal layer, and a trench is introduced inside the JFET region, P-base regions are arranged on both sides of the trench, N⁺ source regions and P⁺ regions are arranged in the P-base regions; a P-type doped region is arranged on sidewalls and a bottom of the trench, a filling region is arranged inside the trench, the P-type doped region is provided with P-type impurities, the P-type doped region is located on the sidewalls and the bottom of the trench, this filling region is filled with a P-type polysilicon and an N-type polysilicon, the N-type polysilicon is surrounded by the P-type polysilicon, and the filling region is located within the P-type doped region.

2. The radiation-hardened SiC MOSFET device structure of claim 1, wherein the source metal layer is provided with interlayer dielectric layers and polysilicon layers, the polysilicon layers are located inside the interlayer dielectric layers.

3. The radiation-hardened SiC MOSFET device structure of claim 1, wherein the number of the P-base regions is two, each P-base region is located on either side of the trench, each P-base region is provided with two N⁺ source regions and one P⁺ region, the N⁺ source regions and the P⁺ region within each P-base region are arranged side by side, the N⁺ source regions are positioned in a middle of the P⁺ region.

4. The radiation-hardened SiC MOSFET device structure of claim 2, wherein the number of the interlayer dielectric layers and the polysilicon layers is several.

5. A preparation method for the radiation-hardened SiC MOSFET device structure of claim 1, comprising the following steps:
S1: the trench is introduced in the JFET region, and P-type impurities are implanted into the sidewalls and the bottom of the trench to form the P-type doped region;
S2: the filling region inside the trench is filled with high-concentration P-type polysilicon and N-type polysilicon, with the N-type polysilicon surrounded by the P-type polysilicon.
